(19) United States
(12) Patent Application Publication
(10) Pub. No.: US 2008/0290858 A1
(43) Pub. Date: Nov. 27, 2008

(54) HAND-HELD ELECTRONIC DEVICE AND OPERATING MODULE THEREOF

(75) Inventors: Shu-Ming Guo, Taipei (TW); Yen-Chih Lin, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ASUSTEK COMPUTER INC., Taipei (TW)

(21) Appl. No.: 12/123,480

(22) Filed: May 20, 2008

(30) Foreign Application Priority Data
May 24, 2007 (TW) 96118494

(51) Int. Cl. H01L 43/06

(52) U.S. Cl. 324/207.2

(57) ABSTRACT

A hand-held electronic device including a casing, a display provided at the casing and an operating module embedded in the casing is provided. The operating module includes an operating key, an elastic film, an elastic wall, a circuit board and a sensing unit. The operating key is provided at the elastic film, and the elastic wall is also provided at the elastic film and is around the operating key. The sensing unit has a first sensing element provided in the operating key and a second sensing element provided at the circuit board.

### CROSS-REFERENCE TO RELATED APPLICATION

This application claims the priority benefit of Taiwan application serial no. 96118494, filed on May 24, 2007. The entirety of the above-mentioned patent application is hereby incorporated by reference herein and made a part of this specification.

### BACKGROUND OF THE INVENTION

1. Field of the Invention

The invention relates to a hand-held electronic device and, more particularly, to a hand-held electronic device having an operating module.

2. Description of the Related Art

With the development of the science and technology, the equipment such as the mobile, the ultra mobile personal computer (UMPC) or the personal digital assistant (PDA) has been popular and essential in the life and work of the modem people. Generally speaking, the hand-held electronic device is usually equipped with an operating module such as a touch pad or a pointing stick for users to operate the hand-held electronic device. For example, the UMPC on the market nowadays is equipped with a touch pad for users to move the choose pointer on the display besides keys for users to operate. In addition, some types of the UMPC are also equipped with pointing sticks, so that users only need to put the finger on the pointing stick to move, and then the operating module under the pointing stick can sense the direction toward which the pointing stick is pushed by the users, and the choose pointer on the display moves toward the direction that the pointing stick is pushed toward. In this way, users can control the moving direction of the pointer at their own pleasure to select the command of the operating system.

In the process of selecting command by a touch pad, a user must touch the touch pad repeatedly to successfully move the choose pointer to the position of the option which needs to be selected, which causes inconvenience for users and reduce the working efficiency of users. On the other hand, since the pointing stick has a larger product size, it does not much correspond to the developing trend which is to be light and slim of the hand-held electronic device.

### BRIEF SUMMARY OF THE INVENTION

The invention provides a hand-held electronic device which has preferred operating convenience.

The invention provides a hand-held electronic device which corresponds to the developing trend which is to be light and slim.

The invention provides an operating module which can promote the operating efficiency of the users.

The invention provides an operating module which includes an operating key, an elastic film, an elastic wall, a circuit board and a sensing unit. The operating key is provided at the elastic film, and the elastic wall is also provided at the elastic film and around the operating key and is away from the operating key at a predetermined distance. The sensing unit has a first sensing element provided in the operating key and a second sensing element provided at the circuit board. In one embodiment of the invention, the operating key has an accommodating space, and the first sensing element is provided at the accommodating space.

In one embodiment of the invention, the first sensing element is a magnetic element, and the second sensing element is a Hall element.

In one embodiment of the invention, the elastic wall and the elastic film are integrally formed.

In one embodiment of the invention, the elastic film includes a plurality of slots provided between the elastic wall and the operating key.

In one embodiment of the invention, the elastic wall has an irregular shape.

In one embodiment of the invention, the operating module further includes a metal dome, and the circuit board has a first surface and a second surface, wherein the metal dome is provided at the first surface, and the second inducing element is provided at the second surface.

In one embodiment of the invention, the operating module further includes a pressing element provided at one side of the elastic film toward the circuit board, and the pressing element is under the operating key.

In one embodiment of the invention, the operating module further includes a protecting cover which is provided at the elastic film and covers the elastic wall and the outer edge of the operating key.

In one embodiment of the invention, the elastic wall is around the operating key as petals.

The invention further provides a hand-held electronic device further includes a casing, a display and the operating module. The display is provided at the housing, and the operating module is embedded in the casing.

In the invention, an operating key is provided at an elastic film, and an elastic wall around the operating key is provided at the elastic film. A sensing unit has a first sensing element provided at the operating key and a second sensing element which is corresponding to the first sensing element and provided at the circuit board. Users can make the sensing unit generate a sensing signal by moving the operating key, and then they can move the choose pointer on the display to the position of the option which needs to be selected quickly.

Since the operating key is provided on the film which is elastic in the invention, users can push or press the operating key easily in both the vertical direction and the horizontal direction, so that the working efficiency of the users and the usage convenience of the hand-held electronic device can be promoted. In addition, an elastic wall around the operating key is provided on the elastic film, so that in the process of pushing the operating key, when the operating key is pushed to the elastic wall, the operating key is pressed by the elastic wall, and the elastic wall applies resilience to the operating key. In this way, when users do not apply a force to the operating key, the operating key returns to the initial position automatically. Since the operating key of the invention returns to the initial position automatically by the action of elastic wall, the invention can effectively avoid that the elastic film loses the elastic action because of the elastic fatigue.

In the hand-held electronic device of the invention, since the operating module moves the choose pointer to the position of the option which needs to be selected by the magnetic induction, compared with the conventional pointing stick, the hand-held electronic device of the invention has a less product size.

These and other features, aspects, and advantages of the present invention will become better understood with regard to the following description, appended claims, and accompanying drawings.

### BRIEF DESCRIPTION OF THE DRAWINGS

FIG. 1 is a schematic diagram showing a hand-held electronic device in a preferred embodiment of the invention.

FIG. 2A is an exploded diagram showing the operating module shown in FIG. 1.

FIG. 2B is a section diagram showing the operating module shown in FIG. 1 along the I-I′ line.

FIG. 3 is a section diagram showing an operating module in another embodiment of the invention.

### DETAILED DESCRIPTION OF THE EMBODIMENTS

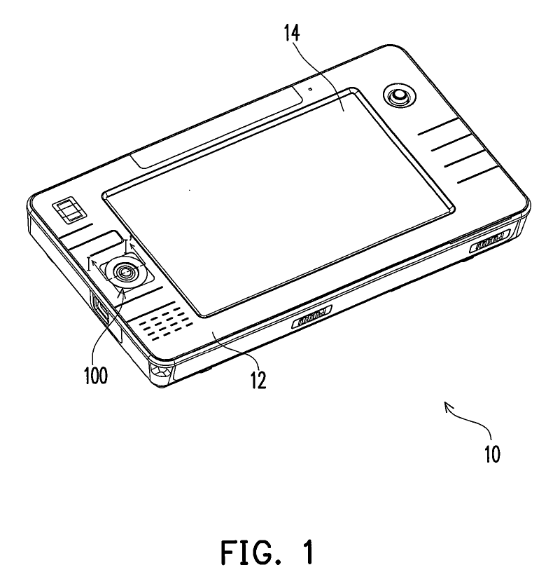

FIG. 1 is a schematic diagram showing a hand-held electronic device in a preferred embodiment of the invention. Please refer to FIG. 1. A hand-held electronic device 10 in FIG. 1 is, for example, an ultra mobile personal computer (UMPC) including a casing 12, a display 14 provided at the casing 12 and an operating module 100. In the embodiment, the operating module 100 is embedded in the casing 12, and users can push or press the operating module 100 by applying a force in a specific direction to the operating module 100 to select the operating system command shown by the display 14. The operating module 100 is described in detail in the embodiment hereinbelow.

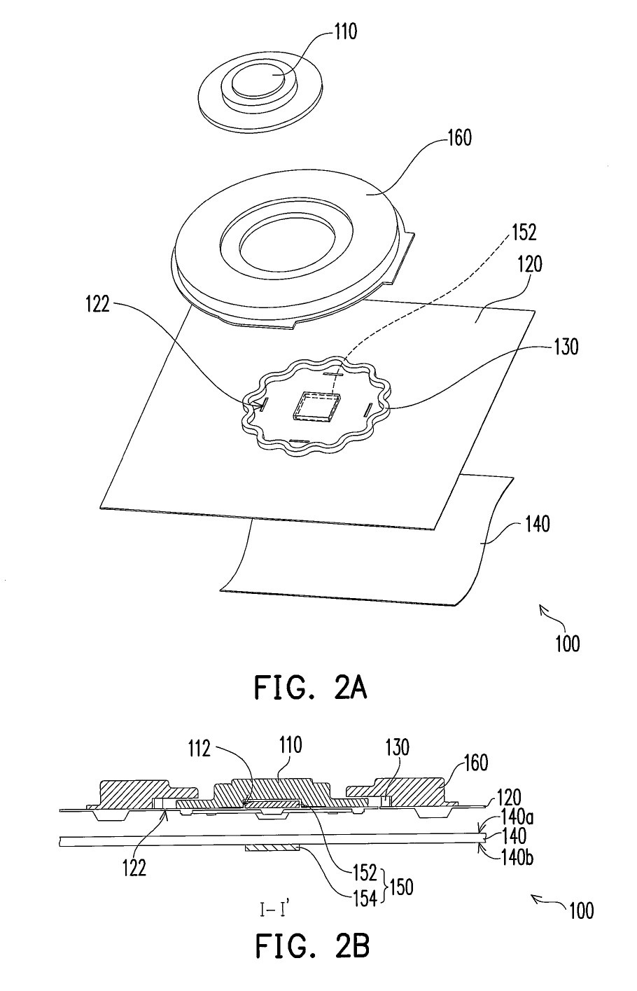

FIG. 2A is an exploded diagram showing the operating module shown in FIG. 1. FIG. 2B is a section diagram showing the operating module shown in FIG. 1 along I-I′ line. Please refer to FIG. 2A and FIG. 2B simultaneously. The operating module 100 of the embodiment includes an operating key 110, an elastic film 120, an elastic wall 130, a circuit board 140 and a sensing unit 150. The operating key 110 is provided on the elastic film 120, and the elastic wall 130 is also provided on the elastic film 120 and around the operating key 110 and is away from the operating key 110 at a predetermined distance.

Please go on referring to FIG. 2A and FIG. 2B. In the embodiment, the sensing unit 150 has a first sensing element 152 provided in the operating key 110 and a second sensing element 154 provided at the circuit board 140. Specifically, the operating key 110 in the embodiment has an accommodating space 112, and the first sensing element 152 is provided in the accommodating space 112. The circuit board 140 has a first surface 140a toward the operating key 110 and a second surface corresponding to the first surface 140a, and the second sensing element 154 is provided at the second surface 140b.

The first sensing element 152 in the embodiment is, for example, a magnetic element, and the second sensing element 154 is, for example, a Hall element, and therefore when a user applies a force to the operating key 110 and makes the operating key 110 deviate toward a predetermined direction, the magnetic element (the first sensing element 152) provided in the operating key 110 generates displacement quantity relatively to the Hall element (the second sensing element 154), and then the magnetic flux between the magnetic element (the first sensing element 152) and the Hall element (the second sensing element 154) changes, and the operating module 100 can move the choose pointer (not shown) in the display 14 (as shown in FIG. 1) via the change of the magnetic flux. Certainly, the operating module in other preferred embodiment also can move the choose pointer in the display 14 by other proper sensing manners.

In the embodiment, the elastic wall 130 and the elastic film 120 are, for example, integrally formed, and the first sensing element 152 such as a magnetic element can be combined with the elastic film 120 in a co-molding or sticking manner to make the magnetic element provided on the elastic film 120 firmly. Since the magnetic element can be provided on the elastic film 120 firmly, the operating module 100 can effectively control the magnetic induction in the vertical direction. On the other hand, the manufacturing manner of forming the elastic wall 130 and the elastic film 120 integrally can reduce the manufacturing cost of the operating module 100 effectively. In addition, the operating module 100 in the embodiment also includes a protecting cover 160. In the embodiment, the protecting cover 160 is provided on the elastic film 120 and covers the elastic wall 130 and the outer edge of the operating key 110. Specifically, the protecting cover 160 is used to protect the elastic film 120 and the elastic wall 130 in the embodiment to protect the elastic film 120 and the elastic wall 130 from the improper external force.

Since the operating key 110 in the embodiment is provided on the elastic film 120, a user can push and move the operating key 110 easily in a horizontal direction or a vertical direction, and the sensing unit 150 can generate sensing signals to move the choose pointer in the display 14 (pleaser refer to FIG. 1) to the position of the option which needs to be selected quickly. In addition, to make users push and move the operating key 110 more easily, the elastic film 120 can have a plurality of slots 122 in the embodiment. The slot 122 can be between the elastic wall 130 and the operating key 110 to facilitate the action of the operating key 110. In addition, since the elastic wall 130 around the operating key 110 is provided on the elastic film 120 in the embodiment, and the elastic wall 130 is, for example, around the operating key 110 as petals, in the process of pushing and moving the operating key 110, if the operating key 110 is moved to the elastic wall 130, the elastic wall 130 is pressed by the operating key 110. Oppositely, the elastic wall 130 applies resilience to the operating key 110. Specifically, when a user pushes the operating key 110 to the elastic wall 130, since the inner wall of the protecting cover 160 restricts the displacement of the elastic wall 130, the elastic wall 130 can apply resilience to the operating key 110 effectively, and then the operating key 110 can return to the initial position automatically in the horizontal direction. In addition, since the operating key 110 returns to the initial position automatically via the action of the elastic wall 130, the invention can avoid that the elastic film loses the elastic action because of the elastic fatigue. Certainly, the operating key 110 in the embodiment also can return to the initial position via the resilience of the elastic film 120 in the vertical direction.

In the embodiment, since the elastic wall 130 is, for example, around the operating key 110 as petals, even if some portion of the elastic wall 130 has cracks, and a user pushes the operating key 110 to the elastic wall 130 having the cracks, the partial elastic wall 130 around the cracks still can provide proper resilience for the operating key 110 effectively to make the operating key 110 return to the initial position automatically. That is, the elastic wall 130 with a petal shape has a preferred elastic strength. Certainly, in the other embodiment, the elastic wall 130 also can have an irregular shape or other proper shape, and it is limited in the invention.

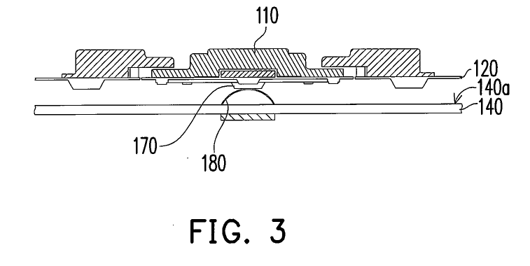

In another preferred embodiment, a metal dome 180 can be provided on the first surface 140a of the circuit board 140, and the a pressing element 170 is provided at one side of the elastic film 120 toward the circuit board 140, wherein the pressing element 170 is under the operating key please refer to FIG. 3 which is a section diagram showing an operating module in another preferred embodiment of the invention.). In the embodiment, the metal dome 180 can provide a supporting force for the operating key 110 in the vertical direction. In addition, when a user presses the operating key 110 and applies a downward pressing force to the metal dome 180 via the pressing element 170, if the user does not apply a downward pressing force to the operating key 110 again, the metal dome 180 can apply upward resilience to the operating key 110 via the pressing element 170, so that the operating key 110 can return to the initial position in a vertical direction. The metal dome 180 is, for example, a metal dome.

To sum up, in the invention, the operating key is provided on an elastic film, and an elastic wall around the operating key is provided on the elastic film. The sensing unit has a first sensing element provided at the operating key and a second sensing element which is provided at the circuit board and corresponding to the first sensing element. Users can make the sensing unit generate an sensing signal by moving the operating key, so that the choose pointer on the display can be moved to the position of the option which needs to be selected quickly. Compared with the conventional technology, since the operating key is provided on the elastic film, users can push and move the operating key in a horizontal direction or a vertical direction easily. In other word, the operating module of the invention can effectively promote the usage convenience of the hand-held electronic device such as an UMPC and increase the operating efficiency of the usage.

In addition, in the process of pushing or pressing the operating key, the provided elastic wall can effectively make the operating key return to the initial position automatically in the horizontal direction, and the elastic film.or the metal dome can effectively make the operating key return to the initial position automatically in the vertical direction. Since the operating key of the invention returns to the initial position automatically in the horizontal direction via the pressing action of the elastic wall, the invention can avoid that the elastic film loses the effect of the elastic action because of the elastic fatigue. That is, the operating module of the invention has a longer usage life (hand-held electronic device has a longer usage life). Since the operating module of the invention moves the choose pointer in the display to the position of the option needs to be selected by, for example, the magnetic induction. Compared with the conventional pointing stick, the hand-held electronic device of the invention has a less product size to meet the developing trend which is to be light and slim.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. An operating module comprising:
an elastic film;
an operating key provided on the elastic film;
an elastic wall provided on the elastic film, wherein the elastic wall is around the operating key and is away from the operating key at a predetermined distance;
a circuit board; and
a sensing unit having a first sensing element and a second sensing element, wherein the first sensing element is provided in the operating key, and the second sensing element is provided at the circuit board.

2. The operating module according to claim 1, wherein the operating key has an accommodating space, and the first sensing element is provided in the accommodating space.

3. The operating module according to claim 1, wherein the first sensing element is a magnetic element, and the second sensing element is a Hall element.

4. The operating module according to claim 1, wherein the elastic wall and the elastic film are integrally formed.

5. The operating module according to claim 1, wherein the elastic film comprises a plurality of slots provided between the elastic wall and the operating key.

6. The operating module according to claim 1, wherein the elastic wall has an irregular shape.

7. The operating module according to claim 1 further comprising a metal dome, wherein the circuit board has a first surface and a second surface, and the metal dome is provided at he first surface, while the second sensing element is provided at the second surface.

8. The operating module according to claim 7 further comprising a pressing element corresponding to the metal dome, wherein the pressing element is provided at one side of the elastic film toward the circuit board and is under the operating key.

9. The operating module according to claim 1 further comprising a protecting cover provided at the elastic film and covering the elastic wall and the outer edge of the operating key.

10. The operating module according to claim 1, wherein the elastic wall is around the operating key as petals.

11. A hand-held electronic device comprising:
a casing;
a display provided at the casing;
an operating module embedded at the housing and comprising:
an operating key;
an elastic film provided on the operating key;
an elastic wall provided on the elastic film, wherein the elastic wall is around the operating key and is away from the operating key at a predetermined distance;
a circuit board; and
a sensing unit having a first sensing element and a second sensing element, wherein the first sensing element is provided in the operating key and the second sensing element is provided at the circuit board.

12. The hand-held electronic device according to claim 11, wherein the operating key has an accommodating space, and the first sensing element is provided in the accommodating space.

13. The hand-held electronic device according to claim 11, wherein the first sensing element is a magnetic element, and the second sensing element is a Hall element.

14. The hand-held electronic device according to claim 11, wherein the elastic wall and the elastic film are integrally formed.

15. The hand-held electronic device according to claim 11, wherein the elastic film comprises a plurality of slots provided between the elastic wall and the operating key.

16. The hand-held electronic device according to claim 11, wherein the elastic wall has an irregular shape.

17. The hand-held electronic device according to claim 11, wherein the operating module further comprises a metal dome, and the circuit board has a first surface and a second surface, and the metal dome is provided at the first surface, while the second sensing element is provided at the second surface.

18. The hand-held electronic device according to claim 17, wherein the operating module further comprises a pressing element corresponding to the metal dome, and the pressing element is provided at one side of the elastic film toward the circuit board and under the operating key.

19. The hand-held electronic device according to claim 11, wherein the operating module further comprises a protecting cover which is provided at the elastic film and covers the elastic wall and the outer edge of the operating key.

20. The hand-held electronic device according to claim 11, wherein the elastic wall is around the operating key as petals.
